(19) United States
(12) Patent Application Publication
(10) Pub. No.: US 2025/0159914 A1
(43) Pub. Date: May 15, 2025

(54) SEMICONDUCTOR DEVICE WITH A MAIN DEVICE REGION AND A CURRENT SENSOR REGION

(71) Applicant: Infineon Technologies Austria AG, Villach (AT)

(72) Inventors: Tillmann Walther, Dresden (DE); Dmitry Balashov, Bannewitz OT Wilmsdorf (DE); Matthias Fiebig, München (DE)

(21) Appl. No.: 18/931,165

(22) Filed: Oct. 30, 2024

(30) Foreign Application Priority Data
Nov. 10, 2023 (DE) 102023211118.7

(51) Int. Cl. H01L 29/739; H01L 29/06; H01L 29/66

(52) U.S. Cl. CPC H10D 12/481; H10D 62/102; H10D 62/127; H10D 12/038

(57) ABSTRACT

A semiconductor device includes a main device region having main device cell regions confined by gate trenches arranged at a first main surface of a semiconductor substrate. A current sensor region has current sensor cell regions confined by gate trenches arranged at the first main surface. An interface region arranged between the main device region and the current sensor region includes a shielding region of a second conductivity type arranged at the first main surface and covering at least partly a bottom of one of the gate trenches confining one of the main device cell regions or one of the current sensor cell regions. The interface region further includes a further region of the second conductivity type arranged at the first main surface, and a gap region of a first conductivity type arranged at the first main surface. The gap region separates the shielding region from the further region.

### TECHNICAL FIELD

The present disclosure relates to a semiconductor device with a main device region and a current sensor region.

### BACKGROUND

Some power devices include current and temperature sensing mechanisms to monitor overcurrent or overtemperature operating conditions. The output of such sensing mechanisms can be passed to other control and protection circuits for controlling the operation of one or more power devices. Such control and protection circuits operate to disable power devices when an overcurrent or overtemperature operating condition is detected. The power devices should be turned off in a proper manner as early as possible to avoid a short circuit or overcurrent situation. Thus, there is a need for a reliable current and temperature sensing approach for power devices, like e.g., power semiconductor devices.

### SUMMARY

According to an example of a semiconductor device, the semiconductor device comprises a semiconductor substrate and a main device region. The main device region comprises a plurality of main device cell regions confined by gate trenches arranged at a first main surface of the semiconductor substrate, wherein gate electrodes are arranged in the gate trenches. The semiconductor device further comprises a current sensor region. The current sensor region comprises a plurality of current sensor cell regions confined by gate trenches arranged at the first main surface of the semiconductor substrate, wherein gate electrodes are arranged in the gate trenches. The semiconductor device further comprises an interface region arranged between the main device region and the current sensor region. The interface region comprises a shielding region of a second conductivity type arranged at the first main surface of the semiconductor substrate and covering at least partly a bottom of one of the gate trenches confining one of the plurality of main device cell regions or one of the plurality of current sensor cell regions. The interface region further comprises a further region of the second conductivity type arranged at the first main surface of the semiconductor substrate, and a gap region of a first conductivity type arranged at the first main surface of the semiconductor substrate. The gap region separates the shielding region from the further region.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements unless indicated otherwise. The elements of the drawings are not necessarily drawn to scale relative to each other. The features of the various illustrated examples can be combined unless they exclude each other.

FIG. 1 illustrates a partial top view of an exemplary semiconductor device;

FIGS. 2A and 2B illustrate cross-sectional views of the semiconductor device;

FIGS. 3A and 3B illustrate cross-sectional views of the semiconductor device;

FIG. 4 illustrates a partial top view of an exemplary semiconductor device;

FIG. 5 illustrates a circuit schematic of an exemplary electronic system; and

FIG. 6 illustrates a top view of a layout for an exemplary semiconductor device.

### DETAILED DESCRIPTION

The making and using of several examples are discussed in detail below. It should be appreciated, however, that the present invention provides many applicable inventive concepts that can be embodied in a wide variety of specific contexts. The specific examples discussed are merely illustrative of specific ways to make and use the invention, and do not limit the scope of the invention.

The terms “having”, “containing”, “including”, “comprising” and the like are open, and the terms indicate the presence of stated structures, elements or features but do not preclude the presence of additional elements or features. The articles “a”, “an” and “the” are intended to include the plural as well as the singular, unless the context clearly indicates otherwise.

The terms “bonded”, “attached”, “connected” and/or “coupled” are not meant to mean that the elements or layers must directly be contacted together; intervening elements or layers may be provided between the “bonded”, “attached”, “connected” and/or “coupled” elements, respectively. However, in accordance with the disclosure, the above-mentioned terms may, optionally, also have the specific meaning that the elements or layers are directly contacted together, i.e. that no intervening elements or layers are provided between the “bonded”, “attached”, “connected” and/or “coupled” elements, respectively.

The term “electrically connected” describes a permanent low-resistive connection between electrically connected elements, for example a direct contact between the concerned elements or a low-resistive connection via a metal and/or heavily doped semiconductor material.

The terms “on” and “over” are not to be construed as meaning only “directly on” and “directly over”. Rather, if one element is positioned “on” or “over” another element (e.g., a layer is “on” or “over” another layer or “on” or “over” a substrate), a further component (e.g., a further layer) may be positioned between the two elements (e.g., a further layer may be positioned between a layer and a substrate if the layer is “on” or “over” said substrate).

Spatially relative terms, such as “beneath,” “below,” “lower,” “above,” “upper”, “under” and the like, are used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Described next, with reference to the figures, are exemplary implementations of a semiconductor device with a main device region and a current sensor region. While the exemplary implementations are described in the context of IGBT (insulated gate bipolar transistor) devices, the exemplary implementations may be realized using other types of transistors such as MOSFET (metal-oxide-semiconductor field-effect transistor) devices, BJT (bipolar junction transistor) devices, JFET (junction field-effect transistor) devices, etc. That means, references to emitter and collector may apply equally to source and drain of a MOSFET, or similar terminals of other types of transistors. In the following implementations, the first conductivity type is n-type and the second conductivity type is p-type for an n-channel device whereas the first conductivity type is p-type and the second conductivity type is n-type for a p-channel device.

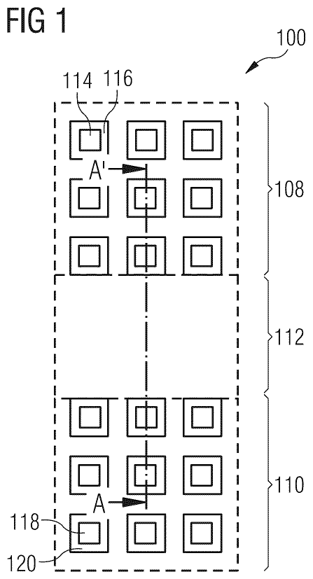

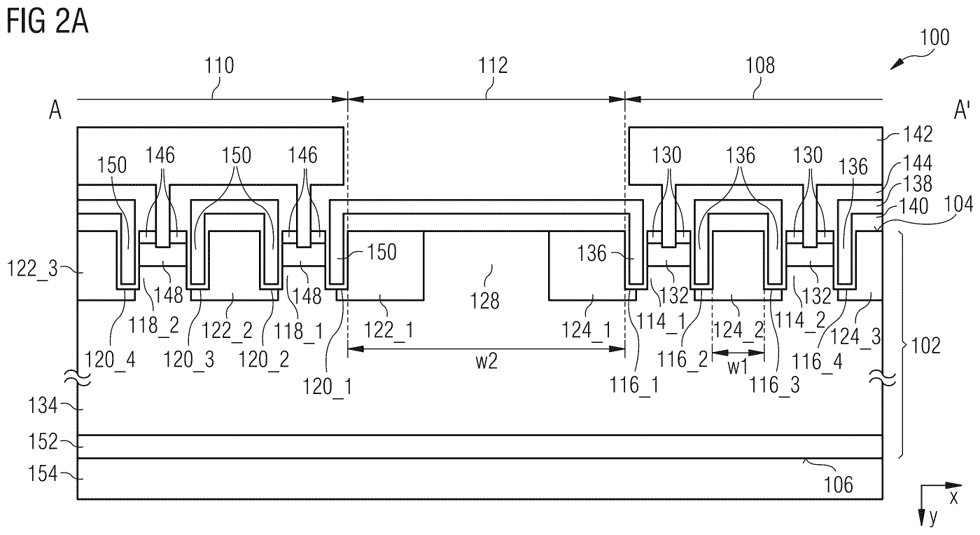

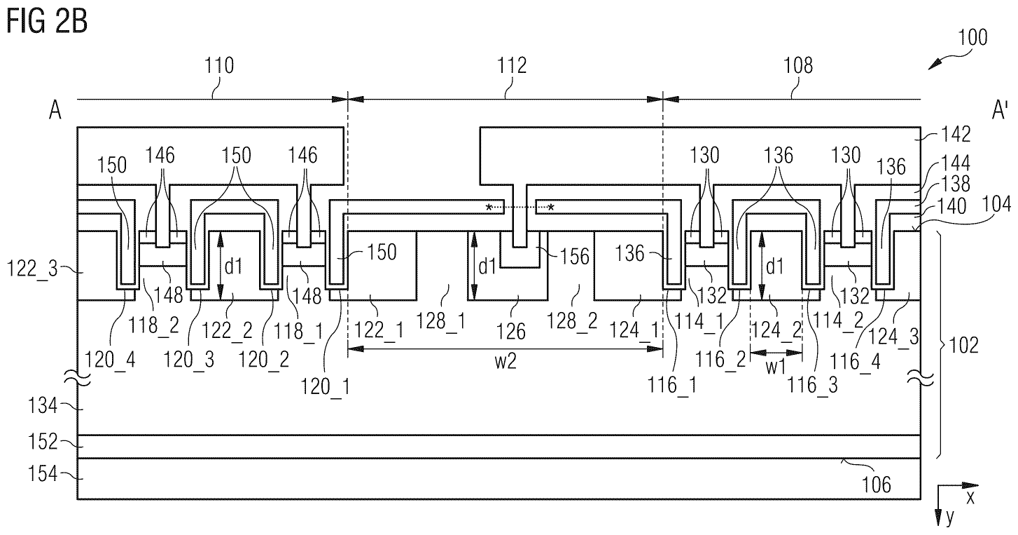

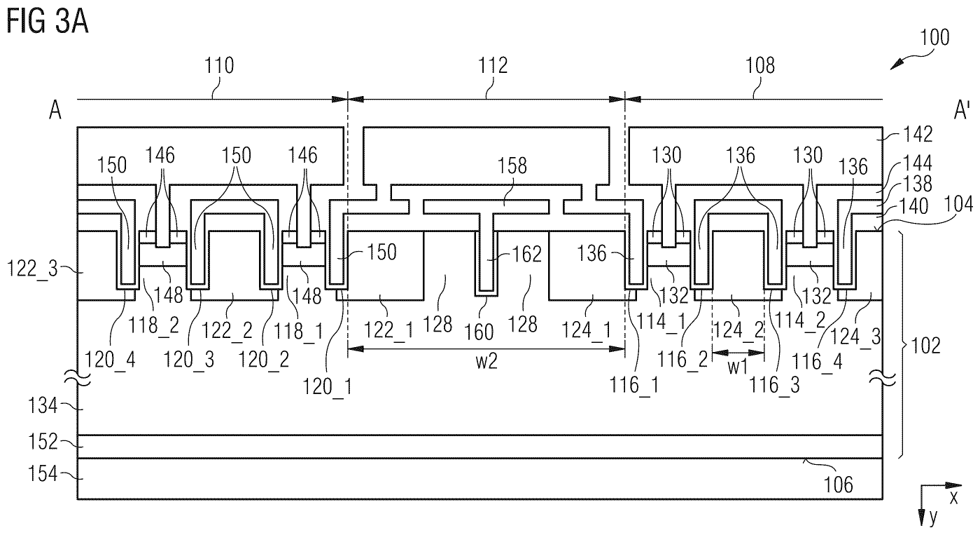

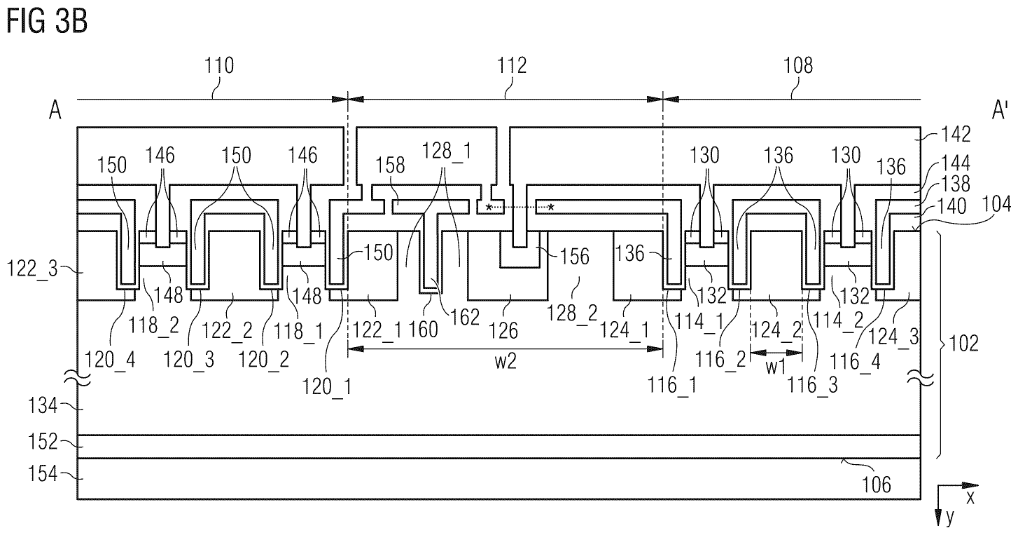

FIG. 1 illustrates a partial top view of an exemplary semiconductor device 100. FIGS. 2A-2B and 3A-3B illustrate cross-sectional views of the semiconductor device 100 along the line labelled A-A′ in FIG. 1. It is noted that FIG. 1 contains less details than FIGS. 2A-2B and 3A-3B for ease of illustration and to provide an unobstructed view.

The semiconductor device 100 includes a semiconductor substrate 102. The semiconductor substrate 102 may include one or more of a variety of semiconductor materials that are used to form semiconductor devices. For example, the semiconductor substrate 102 may include single element semiconductors (e.g. Si, Ge, etc.), silicon-on-insulator semiconductors, binary semiconductors (e.g. SiC, GaN, GaAs, SiGe, etc.), ternary semiconductors (e.g. AlGaN, InGaAs, InAlAs, etc.). The semiconductor substrate 102 may be a bulk semiconductor material or may include one or more additional elements, like e.g., epitaxial layers grown on a bulk semiconductor material, field stop regions, buffer layers, well regions, highly/lowly doped regions, etc. The bulk semiconductor material may be referred to as base semiconductor. The semiconductor substrate 102 has a first main surface 104 and a second mains surface 106 opposite the first main surface 104. The first main surface 104 may be referred to as front surface and the second main surface 106 may be referred to as back surface.

The semiconductor device 100 further includes a main device region 108 and a current sensor region 110. The main device region 108 includes a plurality of main device cell regions 114, 114_1, 114_2. Each of the plurality of main device cell regions 114, 114_1, 114_2 is spatially confined by gate trenches 116, 116_1-116_4 that are arranged at the first main surface 104 of the semiconductor substrate 102 and that extend into the semiconductor substrate 102. Similarly, the current sensor region 110 includes a plurality of current sensor cell regions 118, 118_1, 118_2. Each of the plurality of current sensor cell regions 118, 118_1, 118_2 is spatially confined by gate trenches 120, 120_1-120_4 that are arranged at the first main surface 104 of the semiconductor substrate 102 and that extend into the semiconductor substrate 102. The semiconductor device 100 may be referred to as a trench semiconductor device. The main device region 108 includes power transistor cells that are coupled in parallel to form a power transistor of the semiconductor device 100. The current sensor region 110 includes current sensor transistor cells that are coupled in parallel to form a current sensor transistor of the semiconductor device 100. The power transistor may be referred to as a main transistor. The current sensor cells mirror a current flowing in the main device region 108 and a current flowing through the current sensor cells can be used to sense the current flowing through the main transistor as will be described in more detail in connection with FIG. 5 below. That means, a current that is measured in the current sensor cells represents a current that flows through the main device region 108. The power transistor cells and the current sensor transistor cells may have a same configuration, pitch, etc., but with fewer current sensor transistor cells than power transistor cells, e.g., 1/10, 1/100, 1/1000, 1/10000 or even fewer cells as compared to the power transistor cells. The number of transistors cells that are coupled in parallel defines the capability to conduct current.

As illustrated in cross-sectional views of FIGS. 2A-2B and FIGS. 3A-3B, each of the plurality of main device cell regions 114_1, 114_2 includes source regions 130 of the first conductivity type that are arranged at the first main surface 104 of the semiconductor substrate 102. Each of the plurality of main device cell regions 114_1, 114_2 further includes body regions 132 of the second conductivity type that separate the source regions 130 from a drift region 134 of the first conductivity type that is arranged in the semiconductor substrate 102. The source regions 130 have a higher doping level than the drift region 134. Gate electrodes 136 are arranged in the gate trenches 116_1-116_4 that confine the plurality of main device cell regions 114_1, 114_2. The gate electrodes 136 are separated from the semiconductor substrate 102 by a gate dielectric that is arranged at the sidewalls and at the bottom of the gate trenches 116_1-116_4. The gate electrodes 136 may comprise a metal (e.g., Al, Cu, Ni, Pd, etc.), highly doped polysilicon, etc.

Two neighboring main device cell regions 114_1, 114_2 are separated by an intercell region. The intercell region may be referred to as a spacer region and has a first width w1 that is measured along a horizontal direction x that is parallel to the first main surface 104 of the semiconductor substrate 102. The horizontal direction x may be referred to as a lateral direction. Each intercell region includes a shielding region 124_2, 124_3 of the second conductivity type that is arranged at the first main surface 104 of the semiconductor substrate 102. The shielding regions 124_2, 124_3 may have a same or different doping level as the body regions 132. In one example, the shielding regions 124_2, 124_3 have a lower doping level than the body regions 132. The shielding regions 124_2, 124_3 extend deeper into the semiconductor substrate 102 than the body regions 132. The shielding regions 124_2, 124_3 cover at least partly a bottom of the gate trenches 116_2-116_4 of the neighboring main device cell regions 114_1, 114_2. That means, the shielding regions 124_2, 124_3 extend deeper into the semiconductor substrate 102 than the gate trenches 116_2-116_4, and the gate trenches 116_2-116_4 extend at least partly into the shielding regions 124_2, 124_3. The shielding regions 124_2, 124_3 may be floating regions, i.e., regions with which there is no electrical contact. The shielding regions 124_2, 124_3 may protect the bottoms of the gate trenches 116_2-116_4 from excessive electric fields. In absence of the shielding regions 124_2, 124_3, the bottoms of the gate trenches 116_2-116_4 may be subject to high electric fields during switching operations, e.g., during turn-off, which could jeopardize a correct functionality of the semiconductor device 100.

Gate electrodes 136 of neighboring main device cell regions 114_1, 114_2 are electrically connected to each other via a first conductive layer 138 that is formed over the first main surface 104 of the semiconductor substrate 102. The first conductive layer 138 may comprise a metal (e.g., Al, Cu, Ni, Pd, etc.), highly doped polysilicon, etc. The first conductive layer 138 may comprise a single layer or a stack of layers that comprises different materials. The first conductive layer 138 may include a same material and may be manufactured in a same manufacturing step as the gate electrodes 136. The first conductive layer 138 is segmented and a segment of the first conductive layer 138 contacts the gate electrodes 136 to provide a gate terminal. The first conductive layer 138 is electrically isolated from the shielding regions 124_2, 124_3 and the semiconductor substrate 102 by first isolating structures 140 or a first isolating layer 140. The first isolating structures 140/first isolating layer 140 may comprise a dielectric material. In one example, the first isolating structures 140/first isolating layer 140 may be a LOCOS (Local Oxidation of Silicon) region. In another example, first isolating structures 140/first isolating layer 140 may be an STI (Shallow Trench Isolation) region or any other type of isolation region that comprises at least one of grown and/or deposited oxide or nitride.

The first conductive layer 138 is arranged between the first main surface 104 of the semiconductor substrate 102 and a second conductive layer 142. The first conductive layer 138 and the second conductive layer 142 may be referred to as wiring layers. The second conductive layer 142 may comprise a metal (e.g., Al, Cu, Ni, Pd, etc.), highly doped polysilicon, etc. The second conductive layer 142 may comprise a single layer or a stack of layers that comprises different materials. The second conductive layer 142 is electrically isolated from the first conductive layer 138 by a second isolating layer 144. The second isolating layer 144 may comprise a dielectric material and, in one example, it comprises at least one of oxide and nitride. The second conductive layer 142 is segmented and a segment of the second conductive layer 142 contacts the source regions 130 and the body regions 132 via contact openings to provide an emitter terminal of the main device region 108. The emitter terminal of the main device region 108 may be referred to as a first load terminal. In one example (not illustrated), only the source regions 130 and not the body regions 132 are contacted by the segment of the second conductive layer 142 via the contact openings.

The plurality of current sensor cell regions 118_1, 118_2 may have a similar or same structure as the plurality of main device cell regions 114_1, 114_2. The plurality of current sensor cell regions 118_1, 118_2 include source regions 146 of the first conductivity type, body regions 148 of the second conductivity type and a drift region 134 of the first conductivity type that is common to the drift region 134 of the plurality of main device cell regions 114_1, 114_2. The current sensor cell regions 118_1, 118_2 further include gate electrodes 150 that are connected to each other via the first conductive layer 138 to provide a gate terminal. The gate electrodes 150 are separated from the semiconductor substrate 102 by a gate dielectric. A segment of the second conductive layer 142 contacts the source regions 146 and the body regions 148 of the current sensor cell regions 118_1, 118_2 via contact openings to provide an emitter terminal of the current sensor region 110. Two neighboring current sensor cell regions 118_1, 118_2 are separated by an intercell region that includes a shielding region 122_2, 122_3.

A collector region 152 of the second conductivity type is formed at the second main surface 106 of the semiconductor substrate 102. The collector region 152 is common to the main device cell regions 114_1, 114_2 and the current sensor cell regions 118_1, 118_2. It is noted that for devices that are not IGBTs, such as MOSFETs, the collector region 152 of the second conductivity type is replaced by a drain region of the first conductivity type. A third conductive layer 154 is formed over the second main surface 106 of the semiconductor substrate 102. The third conductive layer 154 may comprise a metal (e.g., Al, Cu, Ni, Pd, etc.), highly doped polysilicon, etc. The third conductive layer 154 may comprise a single layer or a stack of layers that comprises different materials. The third conductive layer 154 contacts the collector region 152 to provide a common collector terminal of the main device region 108 and the current sensor region 110. The collector terminal may be referred to as a second load terminal.

Within the main device region 108, the gate electrodes 136 are electrically connected together, the source regions 130 are electrically connected together and there is a common collector region to form the plurality of power transistor cells that are coupled in parallel. The parallel connected power transistor cells form the power transistor of the semiconductor device 100. Within the current sensor region 110, the gate electrodes 150 are electrically connected together, the source regions 146 are electrically connected together and there is a common collector region to form the plurality of current sensor cells that are coupled in parallel. The parallel connected current sensor cells form the current sensor transistor of the semiconductor device 100.

Within the plurality of main device cell regions 114_1, 114_2 and the plurality of current sensor cell regions 118_1, 118_2, channels form in the body regions 132, 148 along the gate trenches 116_1-116_4, 120_1-120_4 to provide an electrically conductive connection between the source regions 130, 146 and the drift region 134. The channels are controlled by a voltage applied to the gate electrodes 136, 150. Within the main device region 108 of the semiconductor device 100, a load current flows in a vertical direction y between the first load terminal at the first main surface 104 of the semiconductor substrate 102 and the second load terminal at the second main surface 106 of the semiconductor substrate 102. The vertical direction y is perpendicular to the horizontal direction x. As explained above, the current sensor cells located in the current sensor region 110 mirror the current flowing in the power transistor cells in the main device region 108. The semiconductor device 100 may be referred to as vertical power semiconductor device and may be configured to conduct load currents of more than 1 A or more than 10 A or more than 30 A or hundreds of A, and may be further configured to block voltages between load terminals in the range of tens up to several thousands of volts, e.g. 10V, 400 V, 650V, 1.2 kV, 1.7 kV, 3.3 kV, 4.5 kV, 5.5 kV, 6 kV, 6.5 kV.

As illustrated in the partial top view of FIG. 1 and in cross-sectional views of FIGS. 2A-2B and FIGS. 3A-3B, the semiconductor device 100 further includes an interface region 112 that separates the main device region 108 from the current sensor region 110. The interface region 112 is arranged between the main device region 108 and the current sensor region 110 along the horizontal direction x. The interface region 112 may be referred to as a transition region and has a second width w2 that is measured along the horizontal direction x. The width w2 of the interface region 112 may be greater than the width w1 of at least one of the intercell regions of the main device cell regions 114_1, 114_2 and the intercell regions of the current sensor cell regions 118_1, 118_2. In one example (not illustrated), outermost cells (i.e., the ones close to the interface region 112) of the main device region 108 and/or the current sensor region 110 may be hole collector cells that do not include source regions. The hole collector cells may allow charge carriers (e.g., holes) to be quickly removed out of the drift region 134 in certain modes of operation, e.g., at turn-off of the power transistor cells.

The interface region 112 includes a shielding region 122_1 of a second conductivity type that is arranged at the first main surface 104 of the semiconductor substrate 102. As illustrated in the cross-sectional views of FIGS. 2A-2B and FIGS. 3A-3B, the shielding region 122_1 covers at least partly a bottom of the gate trench 120_1 of the current sensor region 110. The shielding region 122_1 shields high electric fields from the bottom of the gate trench 120_1 that is located at an edge of the current sensor region 110 facing the main device region 108. That means, the shielding region 122_1 is located at the edge or at the periphery of the current sensor region 110. The shielding region 122_1 may have same or similar dimensions and doping level and may be manufactured in a same manufacturing step as the shielding regions 122_2, 122_3 of the current sensor region 110.

In other examples (not illustrated), the shielding region 122_1 of a second conductivity type is arranged at an edge or at a periphery of the main device region 108 and shields a bottom of the gate trench 116_1 that is located at the edge of the main device region 108 facing the current sensor region 110. The shielding region 122_1 may have same or similar dimensions and doping level and may be manufactured in a same manufacturing step as the shielding regions 124_2, 124_3 of the main device region 108. Generally, the shielding region 122_1 of a second conductivity type covers at least partly a bottom of one of the gate trenches confining one of the plurality of main device cell regions 114_1, 114_2 or one of the plurality of current sensor cell regions 118_1, 118_2.

The interface region 112 further includes a further region 124_1, 126 of the second conductivity type. In one example, as illustrated in the cross-sectional views of FIGS. 2A-3A, the further region 124_1 is a further shielding region 124_1 of the second conductivity type that is arranged at the first main surface 104 of the semiconductor substrate 102. The further shielding region 124_1 covers partly a bottom of the gate trench 116_1 of the main device region 108. The further shielding region 124_1 shields high electric fields from the bottom of the gate trench 116_1 that is located at an edge of the main device region 108 facing the current sensor region 110. That means, the further shielding region 124_1 is located at the edge or at the periphery of the main device region 108. The further shielding region 124_1 may have same or similar dimensions and doping level and may be manufactured in a same manufacturing step as the shielding regions 124_2, 124_3 of the main device region 108. In other examples (not illustrated), the further shielding region 124_1 may cover at least partly a bottom of one of the gate trenches 122, 122_1-122_4 of the current sensor region 110. Generally, the shielding region 122_1 of the second conductivity type of the interface region 112 is arranged at an edge of one the main device region 108 or the current sensor region 110, and the further shielding region 124_1 of the second conductivity type of the interface region 112 is arranged at an edge of the other one the main device region 108 or the current sensor region 110.

In another example, as illustrated in the cross-sectional views of FIGS. 2B-3B, the further region 126 of the second conductivity type is a region 126 of the second conductivity type that is arranged at the first main surface 104 of the semiconductor substrate 102 and that is located between the shielding region 122_1 of the interface region 112 and a shielding region 122_1, 124_1 that is located at the edge of one of the main device region 108 or the current sensor region 110. In one example, the further region 126 may have a same or similar doping level as the shielding regions 124_2, 124_3, 122_2, 122_3 of the main device region 108 or the current sensor region 110. In one example, the further region 126 may extend from the first main surface 104 of the semiconductor substrate 102 to a same depth d1 as the shielding regions 124_2, 124_3, 122_2, 122_3 of the main device region 108 or the current sensor region 110. In one example, the further region 126 may be manufactured in a same manufacturing step as shielding regions 124_2, 124_3, 122_2, 122_3 of the main device region 108 or the current sensor region 110.

In the example as illustrated in the cross-sectional views of FIGS. 2B-3B, the further region 126 of the second conductivity type is electrically connected to the source regions 130 of the main device region 108 via contact openings. The further region 126 may include a contact region 156 of the second conductivity type that improves the electrical contact between the source regions 130 of the main device region 108 and the further region 126. The contact region 156 may have a higher doping level than the further region 126 and a same or similar doping level as the body regions 132, 148 of the main device region 108 and the current sensor region 110. The contact region 156 may be manufactured in a same manufacturing step as the body regions 132, 148 of the main device region 108 and the current sensor region 110. The further region 126 may allow charge carriers (e.g., holes) to be quickly removed out of the drift region 134 in certain operating modes, e.g., at turn-off of the power transistor cells. In other examples (not illustrated), the further region 126 of the second conductivity type is electrically connected to the source regions 146 of the current sensor region 110, or the further region 126 is floating.

The interface region 112 further includes a gap region 128, 128_1 of the first conductivity type that is arranged at the first main surface 104 of the semiconductor substrate 102. The gap region 128, 128_1 separates the shielding region 122_1 of the second conductivity type from the further region 124_1, 126 of the second conductivity type. There is no physical connection between the shielding region 122_1 of the second conductivity type and the further region 124_1, 126 of the second conductivity type, and the shielding region 122_1 and the further region 124_1, 126 are spatially separated from each other. Because of the physical separation of the shielding region 122_1 from the further region 124_1, 126, the shielding region 122_1 is electrically isolated from the further region 124_1, 126 by the gap region 128, 128_1. The gap region 128, 128_1 is arranged between the shielding region 122_1 of the second conductivity type and the further region 124_1, 126 of the second conductivity type along the horizontal direction x. In one example, the gap region 128, 128_1 has a same doping level as the drift region 134, and the gap region 128, 128_1 and the drift region 134 are a contiguous region. In another example, the gap region 128, 128_1 has a higher doping level than the drift region 134. As illustrated in the cross-sectional views of FIGS. 2B-3B, in one example, there is a further gap region 128_2 of the first conductivity type that is arranged at the first main surface 104 of the semiconductor substrate 102. The further gap region 128_2 is arranged between the further region 124_1, 126 of the second conductivity type and a shielding region 122_1, 124_1 that is located at the edge of one of the main device region 108 or the current sensor region 110 along the horizontal direction x.

As previously described, the gate electrodes 136 of the main device region 108 are connected to each other via the first conductive layer 138 and the gate electrodes 150 of the current sensor region 110 are connected to each other via the first conductive layer 138. As illustrated in the cross-sectional view of FIGS. 2A-2B, the gate electrodes 136 of the main device region 108 are electrically connected to the gate electrodes 150 of the current sensor region 110 via the first conductive layer 138. In the example of FIG. 2B, part of the electrical connection within the first conductive layer 138 is located in a plane that is not visible in FIG. 2B (as indicated in FIG. 2B by a dotted line and asterisks). That means, the power transistor of the main device region 108 is switched on/off at the same time as the current sensor transistor of the current sensor region 110. That means, the power transistor of the main device region 108 and the current sensor transistor of the current sensor region 110 are switched on/off concurrently. In one example, the power transistor and the current sensor transistor may be switched on or turned on by applying a positive voltage to the gate electrodes 136 and to the gate electrodes 150. Further, the power transistor and the current sensor transistor may be switched off or turned off by applying zero or a negative voltage to the gate electrodes 136 and to the gate electrodes 150.

As illustrated in the cross-sectional view of FIG. 3A, in one example, the gate electrodes 136 of the main device region 108 are electrically connected to the gate electrodes 150 of the current sensor region 110 via the second conductive layer 142. In another example, as illustrated in the cross-sectional view of FIG. 3B, the gate electrodes 136 of the main device region 108 are electrically connected to the gate electrodes 150 of the current sensor region 110 via the first conductive layer 138 and via the second conductive layer 142. Part of the electrical connection within the first conductive layer 138 is located in a plane that is not visible in FIG. 3B (as indicated in FIG. 3B by a dotted line and asterisks). Generally, the gate electrodes 136 of the main device region 108 are electrically connected to the gate electrodes 150 of the current sensor region 110 via at least the first conductive layer 138. The electrical connection of the gate electrodes 136 of the main device region 108 with the gate electrodes 150 of the current sensor region 110 is arranged at least partly over the gap region 128, 128_1.

The implementation of the gap region 128, 128_1 allows for a reduction or a suppression of a leakage current flowing from the main device region 108 to the current sensor region 110 or vice versa. Without the presence of the gap region 128, 128_1, when the power transistor and the current sensor transistor are switched off, a parasitic leakage current may flow from the main device region 108 to the current sensor region 110 or vice versa. A leakage path may occur involving body regions 132, 148 of the main device region 108 and the current sensor region 110, and a channel may be formed connecting the body regions 132, 148. For example, the parasitic leakage current may occur when the semiconductor device 100 is operated at a high temperature. The parasitic leakage current may negatively affect an operation of the semiconductor device 100 in a state where the power transistor and the current sensor transistor are both switched off. For example, a measurement of a temperature of the semiconductor device 100 may be performed when the power transistor and the current sensor transistor are switched off. In the absence of the gap region 128, 128_1, this temperature measurement may be distorted.

As illustrated in the cross-sectional views of FIGS. 3A-3B, the semiconductor device 100 may further include a shielding structure 158 that is arranged in the first conductive layer 138. The shielding structure 158 is arranged at least partly over the gap region 128, 128_1. In one example, the shielding structure 158 is arranged over a center of the gap region 128, 128_1. Besides, the shielding structure 158 is arranged at least partly below a segment of the second conductive layer 142 that electrically connects the gate electrodes 136 of the main device region 108 with the gate electrodes 150 of the current sensor region 110. The shielding structure 158 shields or mitigates the influence of a gate signal that is applied to the segment of the second conductive layer 142 that electrically connects the gate electrodes 136 of the main device region 108 with the gate electrodes 150 of the current sensor region 110 on the semiconductor substrate 102. The implementation of the shielding structure 158 allows for a further reduction or suppression of a formation of a conductive path for charge carriers between the main device region 108 and the current sensor region 110. In one example, the shielding structure 158 is electrically biased and is electrically connected to the source regions 146 of the current sensor region 110. In other examples, the shielding structure 158 is electrically connected to the source regions 130 of the main device region 108, or the shielding structure 158 is floating.

As illustrated in the cross-sectional views of FIGS. 3A-3B, the semiconductor device 100 may further include at least one isolation trench 160 that is arranged at the first main surface 104 semiconductor substrate 102 and that extends into the gap region 128, 128_1. An electrode 162 is arranged in the isolation trench 160. The electrode 162 is separated from the semiconductor substrate 102 by a dielectric that is arranged at the sidewalls and at the bottom of the isolation trench 160. As illustrated in FIGS. 3A-3B, the isolation trench 160 divides the gap region 128, 128_1 into two sections. In one example, the electrode 162 is electrically biased and is electrically connected to the source regions 146 of the current sensor region 110. In other examples, the electrode 162 is electrically connected to the source regions 130 of the main device region 108, or the electrode 162 is floating. By the implementation of the at least one isolation trench 160 that is filled with the dielectric and the electrode 162, the parasitic current flow from the main device region 108 to the current sensor region 110 or vice versa is further reduced.

In the example of FIGS. 3A-3B, one isolation trench 160 is arranged at the first main surface 104 of the semiconductor substrate 102 and extends into the gap region 128, 128_1. In other examples (not illustrated), two or more isolation trenches are arranged at the first main surface 104 of the semiconductor substrate 102 and extend into the gap region 128, 128_1. The two or more isolation trenches may be arranged in parallel to one another. In further examples (not illustrated), one or more isolation trenches may be arranged in the further gap region 128_2 of FIGS. 2B-3B. The at least one isolation trench 160 may have at least one of a same width and a same depth as the gate trenches 116, 116_1-116_4, 120, 120_1-120_4 of the current sensor region 110 and the main device region 108. Such a regular structure allows for an eased manufacturing of the semiconductor device 100 and manufacturing cost are reduced. The at least one isolation trench 160 may have any type of shape, for example, an open shape such as a straight stripe or a closed shape such as a ring shape.

As illustrated in the example of FIGS. 3A-3B, the electrode 162 that is arranged in the at least one isolation trench 160 is electrically connected to the shielding structure 158 and there is a physical connection between those two elements. In another example (not illustrated), only one of the at least one isolation trench 160 and the shielding structure 158 are implemented in the semiconductor device 100. In yet another example (not illustrated), the electrode 162 that is arranged in the at least one isolation trench 160 and the shielding structure 158 are spatially separated and/or electrically isolated from each other.

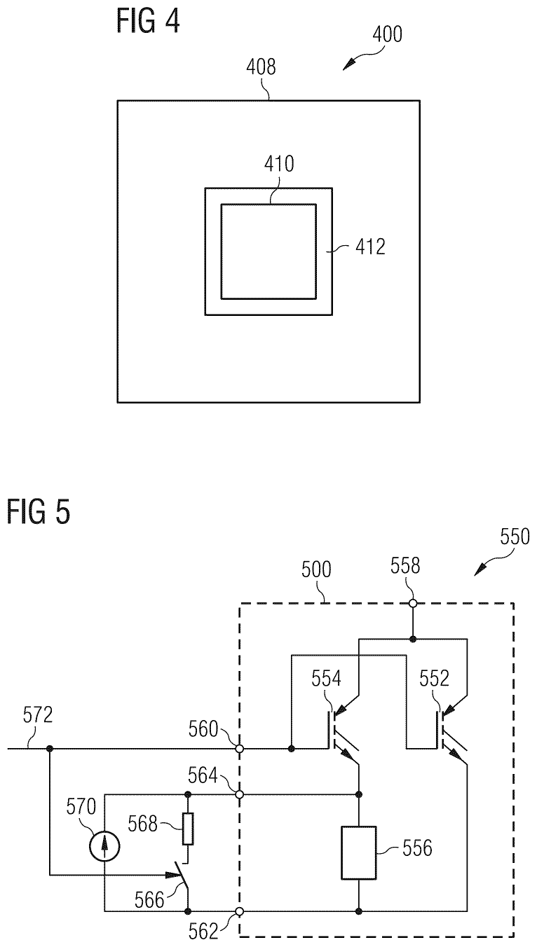

FIG. 4 illustrates a further partial top view of an exemplary semiconductor device 400. Similar to the semiconductor device 100 of FIGS. 1, 2A-2B, 3A-3B, the semiconductor device 400 includes a main device region 408, a current sensor region 410 and an interface region 412. Within the semiconductor device 400, the current sensor region 410 is embedded in the main device region 408. In the example of FIG. 4, the interface region 412 completely laterally surrounds the current sensor region 410. Also, a gap region (not illustrated) that is included in the interface region 412 completely surrounds the current sensor region 410 to reduce or suppress a leakage current flowing from the main device region 408 to the current sensor region 410 or vice versa as explained above. In other examples (not illustrated), the gap region may not completely surround the current sensor region 410. Instead, the gap region may at least partly surround the current sensor region 410 to suppress a leakage current flowing from the main device region 408 to the current sensor region 410 or vice versa as explained above.

The semiconductor devices 100, 400 as illustrated and described in connection with FIGS. 1, 2A-2B, 3A-3B, and 4 are provided as examples. Other examples may differ from what is illustrated and described with regard to FIGS. 1, 2A-2B, 3A-3B, and 4. In one example, there may be additional layers arranged over the first main surface 104 and over the second mains surface 106 of the semiconductor substrate 102. Those additional layers may be isolating layers and/or conductive layers. In one example, the shape and position of the gate trenches, the source regions, the body regions and the one or more isolation trenches may differ from what is illustrated and described in connection with FIGS. 1, 2A-2B, 3A-3B, and 4.

In one example, the gate trenches 116, 116_1-116_4, 120, 120_1-120_4 may be arranged in an array-, grid- or matrix-configuration similar to the examples as illustrated and described in connection with FIGS. 1, 2A-2B, 3A-3B, and 4. The power transistor cells and the current sensor transistor cells may have the shape of a square, hexagon or polygon, for example. In another example, the gate trenches 116, 116_1-116_4, 120, 120_1-120_4 may have a strip-like configuration where the gate trenches may be arranged as stripes that run in parallel to one another and with semiconductor mesas separating those stripe-shaped gate trenches. In yet another example, the gate trenches may be arranged in a way that is neither parallel nor orthogonal to each other. Generally, the gate trenches may have any type of shape, for example, an open shape such as a straight stripe or, for example, a closed shape such as a grid shape.

FIG. 5 illustrates a circuit schematic of an exemplary electronic system 550 that is configured to sense current and temperature of a semiconductor device 500. The electronic system 550 may be part of a power electronic system such as a DC/DC converter, an AC/DC converter, a DC/AC inverter, an AC/AC converter, etc.

The semiconductor device 500 is part of the electronic system 550 and includes a main transistor 552, a current sensor transistor 554 and a temperature sensor device 556. The main transistor 552, the current sensor transistor 554 and the temperature sensor device 556 form an integrated circuit that is monolithically integrated in the semiconductor device 500. The semiconductor device 500 may be referred to as semiconductor die. A collector region of the main transistor 552 and a collector region of the current sensor transistor 554 are both electrically connected to a collector terminal 558 of the semiconductor device 500. Gate electrodes of the main transistor 552 and gate electrodes of the current sensor transistor 554 are all electrically connected to a gate terminal 560 of the semiconductor device 500. A source region of the main transistor 552 is electrically connected to an emitter terminal 562 of the semiconductor device 500 and a source region of the current sensor transistor 554 is electrically connected to a sense terminal 564 of the semiconductor device 500. The temperature sensor device 556 is electrically connected between the sense terminal 564 and the emitter terminal 562. That means, a first terminal of the temperature sensor device 556 is electrically connected to the sense terminal 564 and a second terminal of the temperature sensor device 556 is electrically connected to the emitter terminal 562.

The main transistor 552 may include a main device region that is similar or identical to a main device region 108, 408 explained above. The current sensor transistor 554 may include a current sensor region that is similar or identical to a current sensor region 110, 410 explained above. The current sensor transistor 554 mirrors a current flowing in the main transistor 552, and a current flowing through the current sensor transistor 554 can be used to sense the current flowing through the main transistor 552 as will be described in more detail below. An interface region including a shielding region, a further shielding region and a gap region is arranged between the main device region and the current sensor region as explained above. The interface region may be similar or identical to an interface region 112, 412 explained above.

In one example, the temperature sensor device 556 includes at least one diode that is configured to sense a temperature of the semiconductor device 500 as will be described in more detail below. An anode terminal of the at least one diode is electrically connected to the sense terminal 564 and a cathode terminal of the at least one diode is electrically connected to the emitter terminal 562. In one example, the temperature sensor device 556 includes a plurality of diodes coupled in series. The plurality of diodes coupled in series may be referred to as a diode stack. In one example, an anti-parallel diode may be coupled between sense terminal 564 and the emitter terminal 562 to protect the main transistor 552 and the semiconductor device 500 from destruction in case of ESD (electrostatic discharge). Implementing diodes to sense the temperature of the semiconductor device 500 is just an example. In other examples, other or additional semiconductor devices, like e.g., a resistor may be implemented to sense the temperature of the semiconductor device 500.

Besides the semiconductor device 500, the electronic system 550 includes further circuit elements that are configured to sense current and temperature of the semiconductor device 500. The electronic system 550 includes a switching device 566 and a current sense resistor 568 coupled in series between the sense terminal 564 and the emitter terminal 562. In one example, the switching device 566 includes a transistor. In one example, the switching device 566 may be controlled by a same signal 572 as the gate terminal 560 of the semiconductor device 500. Further, the electronic system 550 includes a current source 570 coupled between the sense terminal 564 and the emitter terminal 562. The further circuit elements that are configured to sense current and temperature of the semiconductor device 500 are provided as an example. In other examples, there may be different and/or additional circuit elements.

In a first mode of operation, the gate terminal 560 of the semiconductor device 500 and the switching device 566 are switched to a first state. In one example, the first state may be an on-state where a high or positive voltage may be applied to the gate terminal 560 and where the main transistor 552 and the current sensor transistor 554 are conducting. Further, in the first state, the switching device 566 is conducting and couples the sense terminal 564 of the semiconductor device 500 to the current sense resistor 568. In the first mode of operation, a current flowing through the current sensor transistor 554 is sensed by sensing a voltage drop across the current sense resistor 568 as measured between the sense terminal 564 and the emitter terminal 562. The voltage may be sensed at a time when the main transistor 552 and the current sensor transistor 554 are in a secure on-state. A current flowing through the main transistor 552 may be determined based on the current flowing through the current sensor transistor 554 and a ratio of a size of the main transistor 552 to a size of the current sensor transistor 554. In the first mode of operation, the semiconductor device 500 is configured to allow for a measurement of a current in the current sensor transistor 554 and the first mode of operation may be referred to as current sensing mode.

In a second mode of operation, the gate terminal 560 of the semiconductor device 500 and the switching device 566 are switched to a second state. In one example, the second state may be an off-state where a low, zero or negative voltage may be applied to the gate terminal 560 and where the main transistor 552 and the current sensor transistor 554 are non-conducting. Further, in the second state, the switching device 566 is non-conducting and decouples the sense terminal 564 of the semiconductor device 500 from the current sense resistor 568. In the second mode of operation, the current source 570 provides a constant current that flows through the temperature sensor device 556 of the semiconductor device 500. The second-state configuration allows for temperature sensing of the semiconductor device 500 by sensing a voltage drop across the temperature sensor device 556 as measured between the sense terminal 564 and the emitter terminal 562. The voltage drop may be sensed at a time when the main transistor 552 and the current sensor transistor 554 are in a secure off-state. In the second mode of operation, the semiconductor device 500 is configured to allow for a measurement of a temperature of the semiconductor device 500 and the second mode of operation may be referred to as temperature sensing mode.

In the exemplary electronic system 550 as illustrated in FIG. 5, a single terminal of the semiconductor device 500, which is the sense terminal 564, is used for both the current measurement and the temperature measurement. Thus, the sense terminal 564 may be referred to as dual mode sense terminal. Switching between current measurement and temperature measurement is effected via the signal 572. A current is measured using the sense terminal 564 when the gate terminal 560 is switched to a first state and a temperature is measured using the sense terminal 564 when the gate terminal 560 is switched to a second state.

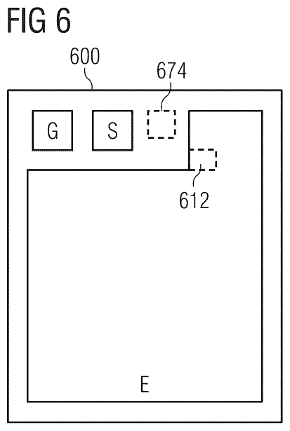

FIG. 6 illustrates a top view of a layout for an exemplary semiconductor device 600. The semiconductor device 600 may be similar or identical to the semiconductor device 500 illustrated and described in connection with FIG. 5. A gate terminal of the semiconductor device 600 is electrically connected to a gate pad G, an emitter terminal of the semiconductor device 600 is electrically connected to an emitter pad E and a sense terminal of the semiconductor device 600 is electrically connected to a sense pad S. The semiconductor device 600 is a vertical device and the gate pad G, the emitter pad E and the sense pad S are arranged over a first main surface of a substrate of the semiconductor device 600. The collector terminal is electrically connected to a collector pad that is arranged over a second main surface of the substrate that is opposite to the first main surface. Thus, the collector pad is out of view in FIG. 6.

The semiconductor device 600 includes a temperature sensor region 674 that includes devices (e.g., semiconductor based or metal thin film based) that form a temperature sensor device of the semiconductor device 600. The semiconductor device 600 further includes a current sensor region 612 that includes current sensor transistor cells that form a current sensor transistor of the semiconductor device 600. The semiconductor device 600 further includes a main device region that is at least partly arranged below the emitter pad E. The main device region includes power transistor cells that form a power transistor of the semiconductor device 600. An interface region including a shielding region, a further shielding region and a gap region is arranged between the main device region and the current sensor region 612 as explained above.

The layout illustrated in FIG. 6 is just an example. In other examples, the temperature sensor region 674 may be located in positions other than those illustrated in FIG. 6. For example, the temperature sensor region 674 may be placed in or near the center of the semiconductor device 600 or the temperature sensor region 674 may be distributed over the semiconductor device 600. Similarly, the current sensor region 612, the gate pad G, the emitter pad E and/or the sense pad S may be located in positions other than those illustrated in FIG. 6. In one example, the emitter pad E may be divided into two or more emitter pads.

The sense pad S is used for both current measurement of the semiconductor device 600 and temperature measurement of the semiconductor device 600. Switching between current measurement and temperature measurement is effected via the gate pad G. Using the sense pad S for both current measurement and temperature measurement leads to minimum effort for accessing the pads, e.g. during bonding, and further, allows for high active area utilization. Besides, an interface region including a shielding region, a further shielding region and a gap region is arranged between the main device region and the current sensor region 612 and suppresses or reduces leakage current flowing from main device region to the current sensor region 612 or vice versa as explained above.

Examples of the present invention are summarized here. Other examples can also be understood from the entirety of the specification and the claims filed herein.

Example 1: A semiconductor device, comprising: a semiconductor substrate; a main device region, comprising: a plurality of main device cell regions confined by gate trenches arranged at a first main surface of the semiconductor substrate, wherein gate electrodes are arranged in the gate trenches; a current sensor region, comprising: a plurality of current sensor cell regions confined by gate trenches arranged at the first main surface of the semiconductor substrate, wherein gate electrodes are arranged in the gate trenches; and an interface region arranged between the main device region and the current sensor region, the interface region comprising: a shielding region of a second conductivity type arranged at the first main surface of the semiconductor substrate and covering at least partly a bottom of one of the gate trenches confining one of the plurality of main device cell regions or one of the plurality of current sensor cell regions, a further region of the second conductivity type arranged at the first main surface of the semiconductor substrate, and a gap region of a first conductivity type arranged at the first main surface of the semiconductor substrate, wherein the gap region separates the shielding region from the further region.

Example 2: The semiconductor device of example 1, wherein the plurality of main device cell regions and the plurality of current sensor cell regions comprise source regions of the first conductivity type, body regions of the second conductivity type and a drift region of the first conductivity type, wherein the body regions separate the drift region from the source regions.

Example 3: The semiconductor device of the preceding example, wherein the drift region and the gap region are a contiguous region.

Example 4: The semiconductor device of any of the preceding examples, wherein the further region is a further shielding region of the second conductivity type arranged at the first main surface of the semiconductor substrate and covering at least partly a bottom of one of the gate trenches confining one of the plurality of main device cell regions or one of the plurality of current sensor cell regions.

Example 5: The semiconductor device of any of examples 2 or 3, wherein the further region is electrically connected to the source regions of the main device cell regions.

Example 6: The semiconductor device of any of the preceding examples, wherein the gap region electrically isolates the shielding region from the further region.

Example 7: The semiconductor device of any of the preceding examples, wherein the interface region completely surrounds the current sensor region.

Example 8: The semiconductor device of any of examples 2 to 7, further comprising: a shielding structure arranged in a first conductive layer arranged over the first main surface of the semiconductor substrate, wherein the shielding structure is arranged over the gap region.

Example 9: The semiconductor device of any of examples 2 to 8, further comprising: at least one isolation trench arranged at the first main surface of the semiconductor substrate and extending into the gap region.

Example 10: The semiconductor device of example 8 and of example 9, wherein an electrode arranged in the at least one isolation trench is electrically connected to the shielding structure.

Example 11: The semiconductor device of examples 8 and of example 9, wherein at least one of the shielding structure and an electrode arranged in the at least one isolation trench is electrically connected to the source regions of the current sensor cell regions.

Example 12: The semiconductor device of any of the preceding examples, wherein the gate electrodes of the main device region are electrically connected to the gate electrodes of the current sensor region through a second conductive layer arranged over the first main surface of the semiconductor substrate.

Example 13: The semiconductor device of example 8 and of example 12, wherein the first conductive layer is arranged between the first main surface of the semiconductor substrate and the second conductive layer.

Example 14: The semiconductor device of any of the preceding examples, wherein

the main device region further comprises: a plurality of shielding regions of the second conductivity type arranged between two neighboring main device cell regions confined by gate trenches of the main device region, wherein the plurality of shielding regions is arranged at the first main surface of the semiconductor substrate and covers at least partly a bottom of the confining gate trenches; and wherein the current sensor region further comprises: a plurality of shielding regions of the second conductivity type arranged between two neighboring current sensor cell regions confined by gate trenches of the current sensor region, wherein the plurality of shielding regions is arranged at the first main surface of the semiconductor substrate and covers at least partly a bottom of the confining gate trenches.

Example 15: The semiconductor device of any of examples 2 to 14, further comprising: an emitter/source pad arranged over the first main surface of the semiconductor substrate and electrically connected to the source regions arranged in the plurality of main device cell regions; a sense pad arranged over the first main surface of the semiconductor substrate and electrically connected to the source regions arranged in the plurality of current sensor cell regions; and a gate pad arranged over the first main surface of the semiconductor substrate and electrically connected to the gate electrodes of the main device region and to the gate electrodes of the current sensor region.

Example 16: The semiconductor device of example 15, further comprising: a temperature sensor region comprising a temperature sensor device, wherein a first terminal of the temperature sensor device is electrically connected to the sense pad.

Example 17: The semiconductor device of example 16, wherein the semiconductor device is configured to allow for a measurement of a current in the current sensor region using the sense pad when the gate pad is switched to a first state, and wherein the semiconductor device is further configured to allow for a measurement of a temperature of the semiconductor device using the sense pad when the gate pad is switched to a second state.

Example 18: The semiconductor device of example 17, wherein the first state is an on-state and the second state is an off-state.

Example 19: The semiconductor device of any of examples 16 to 18, wherein a second terminal of the temperature sensor device is electrically connected to the emitter/source pad.

Example 20: The semiconductor device of any of examples 16 to 19, wherein the temperature sensor device comprises at least one of a resistor and a plurality of diodes coupled in series.

While this invention has been described with reference to illustrative examples, this description is not intended to be construed in a limiting sense. Various modifications and combinations of the illustrative examples, as well as other examples of the invention, will be apparent to persons skilled in the art upon reference to the description. It is therefore intended that the appended claims encompass any such modifications or examples.

What is claimed is:

1. A semiconductor device, comprising:
a semiconductor substrate;
a main device region, comprising:
a plurality of main device cell regions confined by gate trenches arranged at a first main surface of the semiconductor substrate, wherein gate electrodes are arranged in the gate trenches;
a current sensor region, comprising:
a plurality of current sensor cell regions confined by gate trenches arranged at the first main surface of the semiconductor substrate, wherein gate electrodes are arranged in the gate trenches; and
an interface region arranged between the main device region and the current sensor
region, the interface region comprising:
a shielding region of a second conductivity type arranged at the first main surface of the semiconductor substrate and covering at least partly a bottom of one of the gate trenches confining one of the plurality of main device cell regions or one of the plurality of current sensor cell regions;
a further region of the second conductivity type arranged at the first main surface of the semiconductor substrate; and
a gap region of a first conductivity type arranged at the first main surface of the semiconductor substrate, wherein the gap region separates the shielding region from the further region.

2. The semiconductor device of claim 1, wherein the plurality of main device cell regions and the plurality of current sensor cell regions comprise source regions of the first conductivity type, body regions of the second conductivity type and a drift region of the first conductivity type, wherein the body regions separate the drift region from the source regions.

3. The semiconductor device of claim 2, wherein the drift region and the gap region are a contiguous region.

4. The semiconductor device of claim 2, wherein the further region is electrically connected to the source regions of the main device cell regions.

5. The semiconductor device of claim 2, further comprising:
a shielding structure arranged in a first conductive layer arranged over the first main surface of the semiconductor substrate, wherein the shielding structure is arranged over the gap region.

6. The semiconductor device of claim 5, wherein the gate electrodes of the main device region are electrically connected to the gate electrodes of the current sensor region through a second conductive layer arranged over the first main surface of the semiconductor substrate, and wherein the first conductive layer is arranged between the first main surface of the semiconductor substrate and the second conductive layer.

7. The semiconductor device of claim 2, further comprising:
at least one isolation trench arranged at the first main surface of the semiconductor substrate and extending into the gap region.

8. The semiconductor device of claim 2, further comprising:
a shielding structure arranged in a first conductive layer arranged over the first main surface of the semiconductor substrate, wherein the shielding structure is arranged over the gap region; and
at least one isolation trench arranged at the first main surface of the semiconductor substrate and extending into the gap region.

9. The semiconductor device of claim 8, wherein an electrode arranged in the at least one isolation trench is electrically connected to the shielding structure.

10. The semiconductor device of claim 8, wherein at least one of the shielding structure and an electrode arranged in the at least one isolation trench is electrically connected to the source regions of the current sensor cell regions.

11. The semiconductor device of claim 2, further comprising:
an emitter/source pad arranged over the first main surface of the semiconductor substrate and electrically connected to the source regions arranged in the plurality of main device cell regions;
a sense pad arranged over the first main surface of the semiconductor substrate and electrically connected to the source regions arranged in the plurality of current sensor cell regions; and
a gate pad arranged over the first main surface of the semiconductor substrate and electrically connected to the gate electrodes of the main device region and to the gate electrodes of the current sensor region.

12. The semiconductor device of claim 11, further comprising:
a temperature sensor region comprising a temperature sensor device, wherein a first terminal of the temperature sensor device is electrically connected to the sense pad.

13. The semiconductor device of claim 12, wherein the semiconductor device is configured to allow for a measurement of a current in the current sensor region using the sense pad when the gate pad is switched to a first state, and wherein the semiconductor device is further configured to allow for a measurement of a temperature of the semiconductor device using the sense pad when the gate pad is switched to a second state.

14. The semiconductor device of claim 13, wherein the first state is an on-state and the second state is an off-state.

15. The semiconductor device of claim 12, wherein a second terminal of the temperature sensor device is electrically connected to the emitter/source pad.

16. The semiconductor device of claim 12, wherein the temperature sensor device comprises at least one of a resistor and a plurality of diodes coupled in series.

17. The semiconductor device of claim 1, wherein the further region is a further shielding region of the second conductivity type arranged at the first main surface of the semiconductor substrate and covering at least partly a bottom of one of the gate trenches confining one of the plurality of main device cell regions or one of the plurality of current sensor cell regions.

18. The semiconductor device of claim 1, wherein the gap region electrically isolates the shielding region from the further region.

19. The semiconductor device of claim 1, wherein the interface region completely surrounds the current sensor region.

20. The semiconductor device of claim 1, wherein the gate electrodes of the main device region are electrically connected to the gate electrodes of the current sensor region through a second conductive layer arranged over the first main surface of the semiconductor substrate.

21. The semiconductor device of claim 1, wherein:
the main device region further comprises:
a plurality of shielding regions of the second conductivity type arranged between two neighboring main device cell regions confined by gate trenches of the main device region, the plurality of shielding regions being arranged at the first main surface of the semiconductor substrate and covering at least partly a bottom of the confining gate trenches;
the current sensor region further comprises:
a plurality of shielding regions of the second conductivity type arranged between two neighboring current sensor cell regions confined by gate trenches of the current sensor region, the plurality of shielding regions being arranged at the first main surface of the semiconductor substrate and covering at least partly a bottom of the confining gate trenches.
